(19) United States
(12) Patent Application Publication
(10) Pub. No.: US 2009/0103269 A1
(43) Pub. Date: Apr. 23, 2009

(54) HEAT DISSIPATING DEVICE FOR MEMORY CARD

(75) Inventors: CHANG-CHUN LIU, Shenzhen (CN); XIAO-LIN GAN, Shenzhen (CN); YU-KUANG HO, Tu-Cheng (TW)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Chenzhen City (CN); HON HAI PRECISION INDUSTRY CO., LTD., Tu-Cheng (TW)

(21) Appl. No.: 11/962,114

(22) Filed: Dec. 21, 2007

(30) Foreign Application Priority Data
Oct. 18, 2007 (CN) 200710202135.6

(51) Int. Cl. H05K 7/20; H05K 5/00

(52) U.S. Cl. 361/719

(57) ABSTRACT

A heat dissipating device for a memory card includes a first dissipation element and a second dissipation element. The first dissipation element is attached to one side of the memory card for dissipating heat generated by the memory card. The first dissipation element defines a hole at an end thereof. The second dissipation element is attached to the other side of the memory card for dissipating heat generated by the memory card. The second dissipation element includes a hook at an end thereof corresponding to the hole, for hooking the hole to allow the second dissipation element to rotatably connected to the first dissipation element.

### BACKGROUND

1. Field of the Invention

The present invention generally relates to heat dissipating devices. Particularly, the present invention relates to a heat dissipating device for a memory card.

2. Description of Related Art

Memory capacity in computers has become larger and larger as technology forges ahead. At the same time, the memory cards generate more and more heat during use. To protect a memory card from being overheated, a heat dissipating device is popularly used to cool the memory card. The heat dissipating device generally has two pieces positioned at opposite sides of the memory card, and are screwed or studded to be fixed to each other to sandwich the memory card therebetween. Therefore, the heat dissipating device is firmly attached to the sides of the memory card, for providing heat dissipation. However, the assembly or removal of the heat dissipating device to or from the memory card is complicated, and the screws or the studs tend to be lost easily.

### SUMMARY

In one embodiment, a heat dissipating device for a memory card includes a first dissipation element and a second dissipation element. The first dissipation element is attached to one side of the memory card for dissipating heat generated by the memory card, the first dissipation element defines a hole at an end thereof. The second dissipation element is attached to the other side of the memory card for dissipating heat generated by the memory card. The second dissipation element includes a hook at an end thereof corresponding to the hole, for hooking the hole to allow the second dissipation element to be rotatably connected to the first dissipation element.

Other advantages and novel features of the heat dissipating apparatus for memory will become more apparent from the following detailed description of embodiments when taken in conjunction with the accompanying drawings, in which:

### BRIEF DESCRIPTION OF THE DRAWINGS

FIG. 1 is an exploded, isometric view of a heat dissipating device in accordance with an exemplary embodiment, together with a memory card, the heat dissipating device including a first dissipation element and a second dissipation element;

FIG. 2 is an assembled view of FIG. 1, showing the first dissipation element contacting with a side of the memory card and the second dissipation element not contacting with an opposite side of the memory card; and

FIG. 3 is an assembled view of FIG. 1, showing the first and second dissipation elements respectively contacting with opposite sides of the memory card.

### DETAILED DESCRIPTION

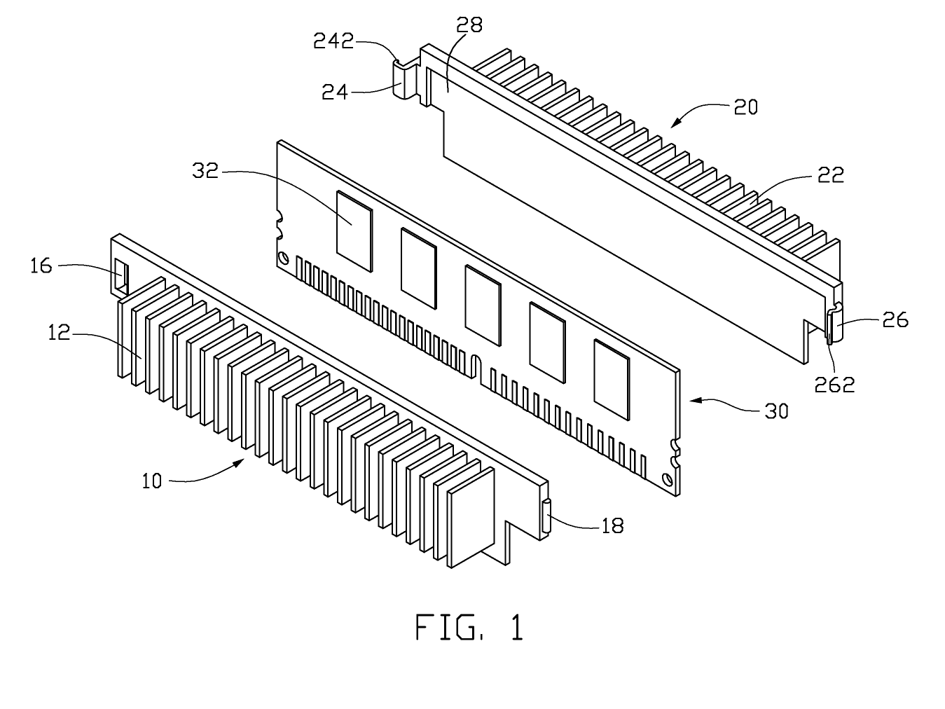

Referring to FIG. 1, a heat dissipating device for a memory card 30, which includes a plurality of chips 32 mounted to opposite sides thereof, includes a first dissipation element 10 and a second dissipation element 20 that are respectively positioned at opposite sides of the memory card 30.

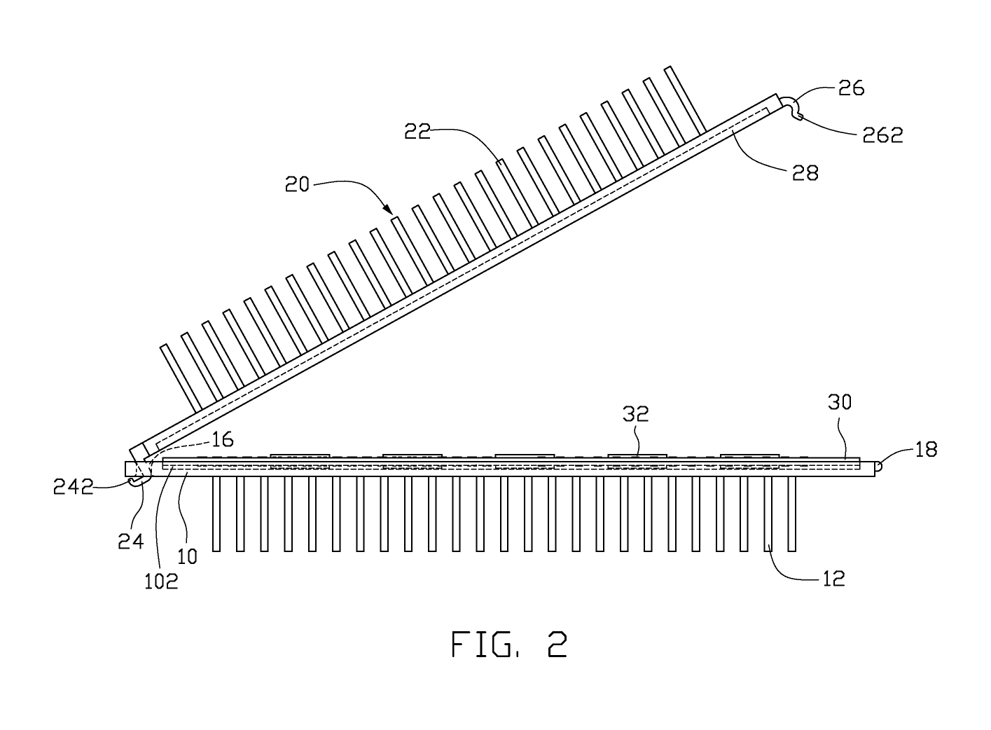

The first dissipation element 10 is generally strip-shaped with a plurality of fins 12 protruding from a side thereof. A first depressed portion 102 (shown in FIG. 2) is defined in an opposite side of the first dissipation element 10. A hole 16 is defined in an end of the first dissipation element 10, and a protrusion 18 protrudes from an end surface at an opposite end of the heat dissipation element 10.

The second dissipation element 20 is also generally strip-shaped with a plurality of fins 22 protruding from a side thereof. A second depressed portion 28 is defined in an opposite side of the second dissipation element 20. An L-shaped hook 24 is extended from an end of the second dissipation element 20 towards a direction opposite to the fins 22. The hook 24 turns back to form a clasp part 242, therefore the hook 24 is generally U-shaped. A clip 26 is extended from the other end of the second dissipation element 20 opposite to the hook 24, towards a same direction as that of the hook 24. The clip 26 can be elastic for being distorted to engage with the protrusion 18 of the first dissipation element 10. An operation part 262 further extends at a distal end of the clip 26 towards a direction away from the second dissipation element 20. The operation part 262 is slightly inclined to the second dissipation element 20.

Referring to FIG. 2, in assembly, the hook 24 of the second dissipation element 20 passes through the hole 16 to be movably restricted by the hole 16 of the first dissipation element 10, with the side having the first depressed portion 102 of the first dissipation element 10 facing the side having the second depressed portion 28 of the second dissipation element 20. The clasp part 24 further hooks a border of the first dissipation element 10 at the hole 16. Therefore, the first and second dissipation elements 10, 20 are rotatably connected. The memory card 30 is mounted to the first dissipation element 10, with the chips 32 of a corresponding side thereof being received in the first depressed portion 102 of the first dissipation element 10.

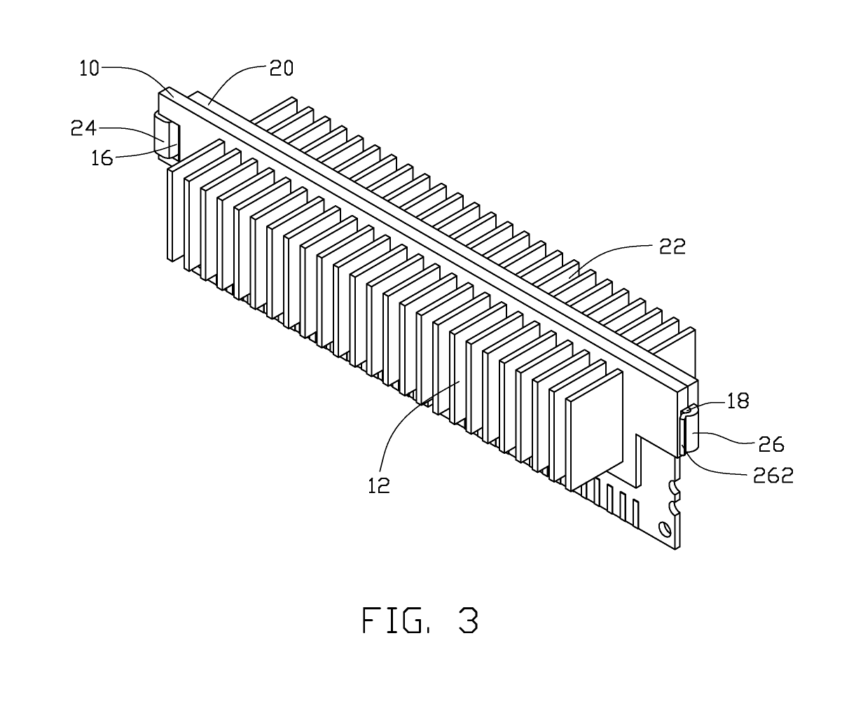

Referring also to FIG. 3, the second dissipation element 20 is rotated about the border of the first dissipation element 10, until the clip 26 is engaged with the protrusion 18. The chips 32 at the other side of the memory card 30 are received in the second depressed portion 28 of the second dissipation element 20. Therefore, corresponding ends of both the first and the second dissipation elements 10, 20 are fixed to each other, with the memory card 30 being sandwiched therebetween.

In disassembling the memory card 20, the operation part 262 is operated to disengage the clip 26 of the second dissipation element 20 from the protrusion 18 of the first dissipation element 10. The second dissipation element 20 is rotated away from the first dissipation element 10. The memory card 30 can then be easily removed from the first dissipation element 10.

For better heat dissipation, heat conduction glue can be adhered between the first and second dissipation elements and the memory.

Moreover, the first and second dissipation elements 10, 20 can be rotatably connected to each other via a hinge, or every two corresponding ends of the first and second dissipation elements 10, 20 are connected to each other via the clip 26 and the protrusion 18.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A heat dissipating device for a memory card, comprising:
a first dissipation element attached to one side of the memory card for dissipating heat generated by the memory card, the first dissipation element defining a hole at an end thereof; and
a second dissipation element attached to the other side of the memory card for dissipating heat generated by the memory card, the second dissipation element comprising a hook at an end thereof corresponding to the hole, for hooking the hole to allow the second dissipation element to be rotatably connected to the first dissipation element.

2. The heat dissipating device as described in claim 1, wherein the hook is extended from an end of the second dissipation element towards the first dissipation element.

3. The heat dissipating device as described in claim 2, wherein a clasp part extends from an end of the hook for hooking a border of the first dissipation element at the hole.

4. The heat dissipating device as described in claim 1, wherein the hook is U-shaped.

5. The heat dissipating device as described in claim 4, wherein a receiving space of the U-shaped hook is configured for receiving a border of the first dissipation element at the hole.

6. The heat dissipating device as described in claim 1, wherein the first dissipation element has a protrusion protruding from an end opposite to the hole, the second dissipation element has a clip protruding an opposite end thereof relative to the protrusion for engaging with the protrusion, therefore fixing the first and second dissipation elements at opposite sides of the memory card.

7. The heat dissipating device as described in claim 6, wherein the clip is elastic for being distorted to engage with the protrusion.

8. The heat dissipating device as described in claim 6, wherein an operation portion is extended from an end of the clip, for being operated to distort the clip, therefore disengaging the protrusion.

9. The heat dissipating device as described in claim 1, wherein the first dissipation element defines a first depressed portion at a side facing the memory card, and the second dissipation element defines a second depressed portion at a side facing the memory card, the first and second depressed portion configured for receiving chips mounted to opposite sides of the memory card.

10. The heat dissipating device as described in claim 1, wherein each of the first and second dissipation elements further comprises fins extended from an opposite side thereof opposite to the memory card.

11. A heat dissipating device for a memory card, comprising:
a first dissipation element; and
a second dissipation element rotatably mounted to an end of the first dissipation element with an end thereof, the second dissipation element and the first dissipation element rotatable round the corresponding ends to make opposite ends thereof to be fixed together, thus configured for sandwiching the memory card therebetween.
